(19) United States
(12) Patent Application Publication
(10) Pub. No.: US 2026/0182283 A1
(43) Pub. Date: Jun. 25, 2026

(54) SELECTIVE HAFNIUM OXIDE ETCH

(71) Applicant: Applied Materials, Inc., Santa Clara, CA (US)

(72) Inventors: Hao ZHUANG, Mountain View, CA (US); Aixi ZHANG, Santa Clara, CA (US); Yi XU, San Jose, CA (US); Yu LEI, Belmont, CA (US); Tuerxun AILIHUMAER, Santa Clara, CA (US); Yixiong YANG, San Jose, CA (US); Srinivas GANDIKOTA, Santa Clara, CA (US); Rongjun WANG, Dublin, CA (US)

(21) Appl. No.: 18/990,817

(22) Filed: Dec. 20, 2024

(51) Int. Cl. H01L 21/311; H01J 37/32

(52) U.S. Cl. CPC H10P 50/285; H01J 37/3244; H01J 2237/334

(57) ABSTRACT

Embodiments described herein generally relate to methods for forming low resistivity contacts for semiconductor device formation. More particularly, embodiments provide methods for selective etching of materials used to form a portion of an electrical contact formed on semiconductor substrates. In some embodiments, a method includes providing a substrate including a gate material and an insulating material disposed at least partially around the gate material, the insulating material including a high-k dielectric. The substrate is exposed to a plasma including a gas that includes one or more of H₂, Ar, Xe, Ne, and Kr. The method further includes etching the high-k dielectric by providing a chlorine-containing precursor while heating the substrate to a temperature of about 450° C. or less.

### FIELD

Embodiments of the present principles generally relate to methods for forming low resistivity contacts for semiconductor device formation. More specifically, the present principles relate to selective etching of materials used to form a portion of an electrical contact formed on semiconductor substrates.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning and/or removing layers, or thinning lateral dimensions of features already present on the surface. Often it is desirable to have an etch process that etches one material faster than another. Such an etch process is said to be selective to the first material versus a second material. As a result of the diversity of materials, circuits, and processes, etch processes have been developed with a selectivity towards a variety of materials.

A wet hydrofluoric (HF) acid etch processes is a commonly used etch processes. However, when dielectrics such as hafnium oxide (HfO₂) are used as gate insulators, the wet HF processes HfO₂ to gate metal etch selectivity is low and the wet HF processes may attack and/or reshape the remaining gate material. Dry etches produced in local plasmas formed within the substrate processing region can etch surfaces by ion bombardment. However, local plasmas will etch HfO₂ and gate metals without selectivity and can damage the substrate through the production of electric arcs.

Thus, there is a need for improved methods and systems for selectively etching materials and structures on semiconductor substrates.

### SUMMARY

Embodiments of the present principles generally relate to forming low resistivity contacts for semiconductor device formation. More particularly, the present principles relate to selective etching of materials on semiconductor substrates.

In some embodiments, a method for dry etching is provided. The method includes providing a substrate including a gate material and an insulating material disposed at least partially around the gate material, the insulating material including a high-k dielectric. The substrate is exposed to a plasma including a gas that includes one or more of H₂, Ar, Xe, Ne, and Kr. The method further includes etching the high-k dielectric by providing a chlorine-containing precursor while heating the substrate to a temperature of about 450° C. or less.

In some embodiments, a method for etching insulating materials is provided. The method includes providing a substrate including a gate material and an insulating material, the insulating material including HfO₂, exposing the substrate to a plasma and etching an exposed surface of the insulating material by exposing the substrate to a metal chloride containing gas while heating the substrate to a temperature of about 450° C. or less. The plasma includes a gas that includes one or more of H₂, Ar, Xe, Ne, and Kr.

In some embodiments, a dry etching method for etching materials on semiconductor substrates is provided. The method includes providing a substrate including a gate material and an insulating material disposed at least partially around the gate material, the insulating material including HfO₂. The method further includes damaging an exposed surface of the insulating material by exposing the substrate to a plasma, reacting the exposed surface of the insulating material with a metal chloride to form HfCl₄, and removing a portion of the exposed surface of the insulating material.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a schematic block diagram of an etch method, in accordance with some embodiments.

FIG. 2A is a cross-sectional view of a portion of a semiconductor structure, in accordance with some embodiments.

FIG. 2B is a cross-sectional view of a portion of a semiconductor structure after a plasma treatment, in accordance with some embodiments.

FIG. 2C is a cross-sectional view of a portion of a semiconductor structure after a chemical etch, in accordance with some embodiments.

FIG. 3A is a chemical depiction of an exposed surface of an insulating material, in accordance with some embodiments.

FIG. 3B is a chemical depiction of an exposed surface of an insulating material after a plasma treatment, in accordance with some embodiments.

FIG. 3C is a chemical depiction of an exposed surface of an insulating material after a chemical etch, in accordance with some embodiments.

FIG. 4 is a schematic cross-sectional view of one embodiment of a process chamber, in accordance with some embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present principles generally relate to methods for forming low resistivity contacts for semiconductor device formation. More particularly, embodiments described herein provide methods for selective etching of materials on semiconductor substrates to enable the formation of an electrical contact structure within a semiconductor device. Selective dry etch processes may be used to remove one material with respect to another material on patterned semiconductor substrates. However, depending on the exposed materials, process gases and process conditions may not provide adequate etch rates of one material without damaging exposed features that include another material. The presence of certain precursor chemicals may directly affect the etch rates and etch selectivities of a variety of materials. It has been discovered that the plasma assisted dry etch methods described herein can selectively etch high-k dielectric materials, such as hafnium oxide (HfO₂). In at least some embodiments, a plasma assisted dry etch method includes a plasma treatment operation and a metal chloride chemical etch operation. The plasma treatment disrupts (or damages) the crystal structure of the exposed HfO₂ increasing the efficiency of a ligand-exchange reaction between the HfO₂ and the metal chloride.

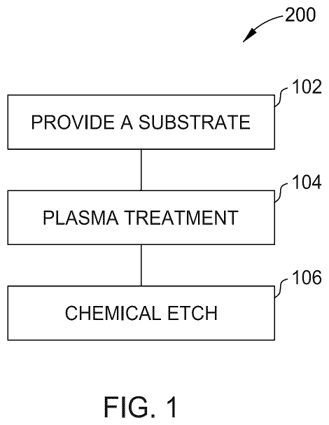

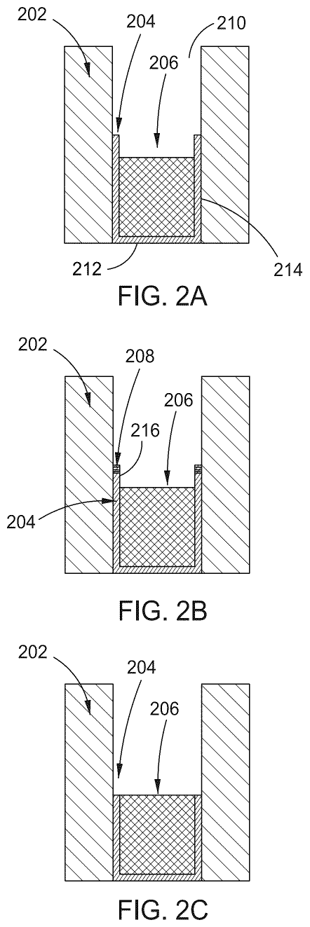

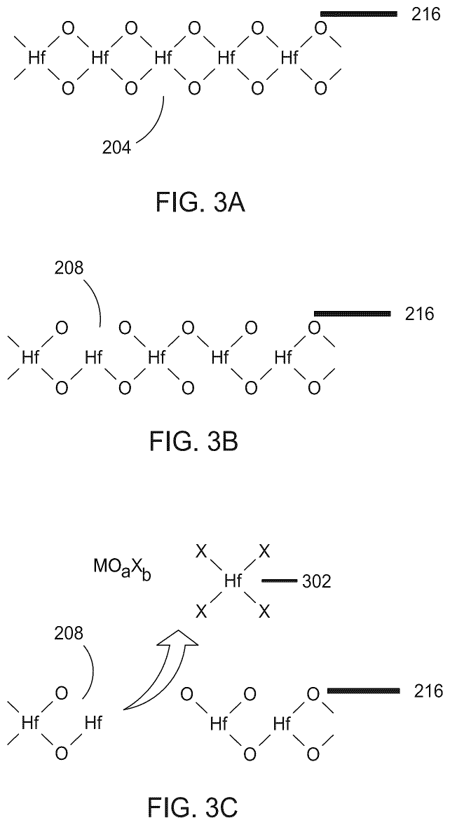

FIG. 1A, is a schematic block diagram of an etch method, in accordance with some embodiments. In the method 100, a plasma treatment and a chemical etch are implemented to selectively etch an insulating material. In one or more embodiments, the method 100 is used to preferentially etch HfO₂. In the discussion of the method 100, references will be made to the views of FIGS. 2A-2C and 3A-3C. However, the views of FIGS. 2A-2C and 3A-3C are merely illustrative of typical embodiments; the method 100 may be used in conjunction with any substrate including an insulating material including HfO₂, to selectively etch the insulating material.

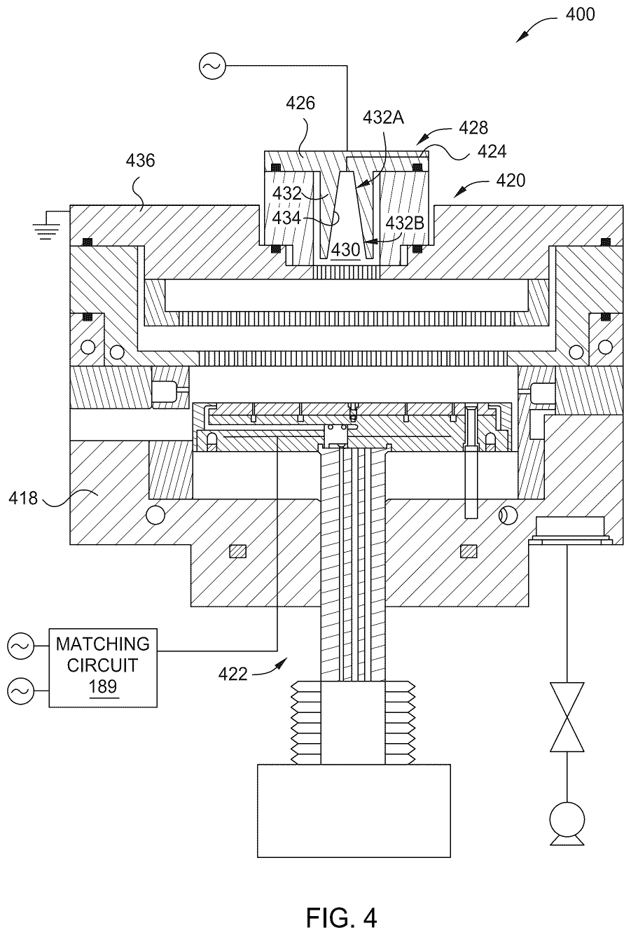

In at least some embodiments, a substrate, such as substrate 200 depicted in FIGS. 2A-2C, is provided at operation 102. In at least some embodiments, the substrate 200 is provided in a processing region of a process chamber, such as the process chamber depicted in FIG. 4. The substrate 200 may include a feature 210 disposed within a dielectric layer 202. In at least some embodiments, the dielectric layer 202 is formed from silicon oxide, silicon nitride, silicon carbon nitride, or combinations thereof. Though only one is shown, the substrate 200 may include any number of features 210. In at least some embodiments, the feature 210 may be a metal contact. A layer of insulating material 204 is disposed within the feature 210, such that the layer of insulating material is disposed over the bottom 212 and at least a portion of the side walls 214 of the feature 210. FIG. 3A is a chemical depiction of the exposed surface 216 of the insulating material 204, in accordance with some embodiments. In at least some embodiments, the insulating material 204 is a high-k dielectric material, such as HfO₂. The HfO₂ may be arranged in a crystal structure as depicted in FIG. 3A. The insulating material 204 is at least partially disposed around a gate metal material 206, such that the insulating material 204 acts as a barrier between the dielectric layer 202 and the gate metal material 206 within the feature 210. In at least some embodiments, the gate metal material 206 includes one or more of W, Mo, TiSi, TiAl, TiAlC, TIN, Ti, TaAl, TaAlC, and TaN.

In at least some embodiments, the feature 210 is at least partially filled with the gate metal material 206, and an excess amount of the insulating material 204 extends above the gate metal material 206, on the side walls 214 of the feature 210. The configuration of the feature 210 illustrated in FIG. 2A can be formed by a plurality of well-known deposition, patterning and etching processes that can include, for example, a conformal insulating material 204 layer CVD or ALD deposition process, one or more gate metal seed, liner and/or barrier layer PVD, CVD or ALD deposition process, and one or more patterning and/or a metal and dielectric layer etch/pull-back processes.

In operation 104 of method 100, the excess insulating material 204 may be selectively etched using a combination of the plasma treatment operation 104 and the chemical etch operation 106 disclosed herein, without damaging the gate metal material 206. In at least some embodiments, the excess insulating material 204 may be completely etched (e.g., completely removed).

In operation 104, a plasma treatment is performed. In at least some embodiments, operation 104 includes exposing the substrate 200 to a plasma. In at least some embodiments, the plasma is a capacitively coupled plasma (CCP), an inductively coupled plasma (ICP), or combinations thereof. The plasma may include one or more gases including H₂, Ar, Xe, Ne, or Kr.

In at least some embodiments, when the substrate 200 is exposed to the plasma an exposed surface 216 of the insulating material 204 (e.g., a surface not covered by the gate metal material 206) is exposed to the plasma. The plasma treatment may break the HfO₂ bonds of the exposed surface 216 of the insulating material 204, partially removing the oxygen, as depicted in FIG. 3B. The resulting damaged surface 208 of the insulating material 204 is more susceptible to the metal chloride facilitated ligand-exchange reaction of the chemical etch operation 106. In at least some embodiments, the plasma treatment operation 104 reduces the thermal budget of the chemical etch operation 106 by about 50° C. to about 150° C.

In at least some embodiments, the plasma treatment operation 104 may include introducing a treatment gas, such as H₂, Ne, Ar, Kr, or Xe, into a process chamber at a flow rate of between about 10 sccm and about 2,000 sccm to achieve a processing pressure of between about 0.001 Torr and about 20 Torr, such as about 0.01 Torr to about 20 Torr, about 0.1 Torr to about 20 Torr, about 1 Torr to about 20 Torr, or about 10 Torr to about 20 Torr. The treatment gas may be flowed into the process chamber for a period of time such as about 20 seconds to about 1,200 seconds, about 60 seconds to about 1,200 seconds, about 300 seconds to about 1,200 seconds, or about 600 seconds to about 1,200 seconds. The plasma may be provided by applying a RF power of between about 0 Watts and about 1,000 Watts to the process chamber at a frequency of between 2 MHz and 60 MHz, such as about 13.56 MHz, such as a RF power of about 0.1 Watts to about 1,000 Watts, about 1 Watt to about 1,000 Watts, about 10 Watts to about 1,000 Watts, about 100 Watts to about 1,000 Watts, or about 500 Watts to about 1,000 Watts. The substrate 200 may be exposed to the plasma for a period of time, such as between about 0 seconds and about 300 seconds, about 0.1 seconds to about 300 seconds, about 1 second to about 300 seconds, about 10 seconds to about 300 seconds, about 100 seconds to about 300 seconds, or about 200 seconds to about 300 seconds. The process chamber pressure may be between about 0.001 Torr and about 20 Torr, and the temperature of the substrate support in the process chamber may be between about 300° C. and about 500° C. while the treatment gas is flowed into the process chamber.

In operation 106 of method 100, a chemical etch is performed. In at least some embodiments, the operation 106 includes exposing the substrate 200 to a chlorine-containing precursor, such as a metal chloride. The operation 106 may be a thermal non-plasma process. In at least some embodiments, the chlorine-containing precursor may include one or more of TiCl₄, AlCl₃, MoCl₅, MoCl₆, WCl₅, WCl₆, BCl₃, HCl, and Cl₂. In at least some embodiments, the chlorine-containing precursor is a metal chloride having the formula of MClₙ. The metal chloride may include one or more of TiCl₄, AlCl₃, MoCl₅, MoCl₆, WCl₅, and WCl₆.

In at least some embodiments, when the substrate 200 is exposed to the chlorine-containing precursor, the HfO₂ of the damaged surface 208 of the insulating material 204 is chemically etched. The HfO₂ of the damaged surface 208 undergoes a ligand-exchange reaction to produce products 302 that are volatile under process conditions, as depicted in FIGS. 2C and 3C. In at least some embodiments, the ligand-exchange reaction may be expressed as equation 1:

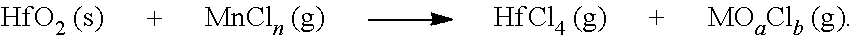

The HfO₂ of the damaged surface 208 is selectively etched by the chlorine-containing precursor, such as a metal chloride. In at least some embodiments, the HfO₂ is selectively etched with an etch ratio of HfO₂:gate metal material of greater than about 5:1, such as greater than about 6:1, greater than about 8:1, greater than about 10:1, greater than about 12:1, or greater than about 20:1. In at least some embodiments, etching the insulating material may have an etched selectivity of about 5 or greater, such as about 8 or greater, about 10 or greater, about 15 or greater, or about 20 or greater.

In at least some embodiments, the chemical etch operation 106 includes, providing a gas containing the chlorine-containing precursor into a process chamber and incubating the substrate 200 with the chlorine-containing precursor while heating the substrate. In at least some embodiments, the chlorine-containing precursor is provided into a process chamber at a flow rate of between about 1 sccm and about 3,000 sccm to achieve a processing pressure of between about 5 Torr and about 300 Torr, such as about 10 Torr to about 300 Torr, about 50 Torr to about 300 Torr, or about 100 Torr to about 300 Torr. The chlorine-containing precursor may be flowed into the process chamber for a period of time such as about 10 seconds to about 1,500 seconds, about 20 seconds to about 1,500 seconds, about 60 seconds to about 1,500 seconds, about 300 seconds to about 1,500 seconds, or about 600 seconds to about 1,500 seconds. In at least some embodiments, the process chamber may be operated at a pressure between about 5 Torr and about 300 Torr, and the substrate may be heated to a temperature of about 450° C. or less, such as about 300° C. to about 450° C., about 325° C. to about 450° C., about 350° C. to about 450° C., or about 400° C. to about 450° C. In at least some embodiments, the substrate is incubated with the chlorine-containing precursor for a period of time such as about 10 seconds to about 1,500 seconds, about 20 seconds to about 1,500 seconds, about 60 seconds to about 1,500 seconds, about 300 seconds to about 1,500 seconds, or about 600 seconds to about 1,500 seconds.

In one or more embodiments, the plasma treatment operation 104 and chemical etch operation 106 may be performed as a cyclic process, such that a first cycle includes a first plasma treatment operation 104 followed by a first chemical etch operation 106, a second cycle includes a second plasma treatment operation 104 followed by a second chemical etch operation 106, a third cycle includes a third plasma treatment operation 104 followed by a third chemical etch operation 106, and so on. Any number of cycles may be performed to reach the desired thickness of the insulating material 204. In at least some embodiments, the insulating material 204 may be completely etched (e.g., completely removed). In at least some of those embodiments, the plasma treatment operation 104 and chemical etch operation 106 may be cyclically repeated until the insulating material 204 is completely etched.

The method 100 may be performed in a suitable etch chamber that is configured to selectively remove a portion of insulating material 204. FIG. 4 is a cross sectional view of an illustrative process chamber 400 suitable for conducting etching processes, such as the etching process described above. The process chamber 400 is configured to remove materials from a material layer disposed on a substrate surface. The process chamber 400 is particularly useful for performing plasma assisted dry etch processes. Examples of process chambers 400 suitable for practicing the disclosed methods include a Selectra™ process chamber, a Siconi™ process chamber, and an Exsel™ chamber which are available from Applied Materials, Santa Clara, California. The etch chamber employed in method 100 may be a standalone chamber, or part of a cluster tool, such as one of the ENDURA® line of cluster tools, also available from Applied Materials, Inc. It is contemplated that other vacuum process chambers available from other manufactures may also be adapted to practice the present methods.

The process chamber 400 provides both heating and cooling of a substrate surface without breaking vacuum. In one embodiment, the process chamber 400 includes a chamber body 418, a lid assembly 420, and a support assembly 422. The lid assembly 420 is disposed at an upper end of the chamber body 418, and the support assembly 422 is at least partially disposed within the chamber body 418.

In one or more embodiments, the lid assembly 420 includes one or more gas inlets 424 (only one is shown) that are at least partially formed within an upper section 426 of the first electrode 428. The one or more process gases enter the lid assembly 420 via the one or more gas inlets 424. The one or more gas inlets 424 are in fluid communication with the cavity 430 at a first end thereof and coupled to one or more upstream gas sources and/or other gas delivery components, such as gas mixers, at a second end thereof. The cavity 430 can include an expanding section 432 that bounds the cavity 430 that is disposed over a substrate.

In one or more embodiments, it is desirable for one or more of the processes described above in relation to method 100 to be performed using a thermal non-plasma processes. However, in one or more embodiments, a first electrode 428 includes the expanding section 432 that bounds the cavity 430. In one or more embodiments, the expanding section 432 is an annular member that has an inner surface or diameter 434 that gradually increases from an upper portion 432A thereof to a lower portion 432B thereof. As such, the distance between the first electrode 428 and a second electrode 436 is variable across the expanding section 432. The varying distance helps control the formation and stability of the plasma generated within the cavity 430.

The expanding section 432 is in fluid communication with the gas inlet 424 as described above. The first end of the one or more gas inlets 424 can open into the cavity 430 at the upper most point of the inner diameter of the expanding section 432. Similarly, the first end of the one or more gas inlets 424 can open into the cavity 430 at any height interval along the inner diameter 434 of the expanding section 432. Although not shown, two gas inlets 424 can be disposed at opposite sides of the expanding section 432 to create a swirling flow pattern or “vortex” flow into the expanding section 432 which helps mix the gases within the cavity 430.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Overall, the plasma assisted dry etch methods of the present disclosure can selectively etch high-k dielectric materials, such as HfO₂ without damaging the remaining gate material. In at least some embodiments, a plasma assisted dry etch method includes a plasma treatment and a thermal metal chloride chemical etch. The plasma treatment disrupts (or damages) the crystal structure of the exposed HfO₂ increasing the efficiency of a ligand-exchange reaction between the HfO₂ and the metal chloride.

While the foregoing is directed to implementations of the present disclosure, other and further implementations of the disclosure may be devised without departing from the basic scope thereof. The present disclosure also contemplates that one or more aspects of the implementations described herein may be substituted in for one or more of the other aspects described. The scope of the disclosure is determined by the claims that follow.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

1. A method for dry etching comprising:
providing a substrate comprising a gate material and an insulating material disposed at least partially around the gate material, the insulating material comprising a high-k dielectric;
exposing the substrate to a plasma comprising a gas that comprises one or more of H₂, Ar, Xe, Ne, and Kr; and
etching the high-k dielectric by providing a chlorine-containing precursor while heating the substrate to a temperature of about 450° C. or less.

2. The method of claim 1, wherein the high-k dielectric comprises HfO₂.

3. The method of claim 2, the chlorine-containing precursor comprises one or more of TiCl₄, AlCl₃, MoCl₅, MoCl₆, WCl₅, WCl₆, BCl₃, HCl, and Cl₂.

4. The method of claim 2, wherein the plasma comprises a capacitively coupled plasma (CCP), an inductively coupled plasma (ICP), or combinations thereof.

5. The method of claim 3, wherein exposing the substrate to the plasma further comprises:
flowing a treatment gas into a process chamber and providing a RF power of between about 0.1 Watts and about 1,000 Watts to the process chamber.

6. The method of claim 3, wherein the plasma comprises H₂.

7. The method of claim 6, wherein the substrate is exposed to the plasma for about 0.1 seconds to about 300 seconds.

8. The method of claim 3, further comprising incubating the substrate with the chlorine-containing precursor for about 10 seconds to about 1,500 seconds.

9. The method of claim 2, further comprising cyclically repeating, exposing the substrate to the plasma and providing the chlorine-containing precursor.

10. A method for etching insulating materials comprising:
providing a substrate comprising a gate material and an insulating material, the insulating material comprising HfO₂;
exposing the substrate to a plasma comprising a gas that comprises one or more of H₂, Ar, Xe, Ne, and Kr; and
etching an exposed surface of the insulating material by exposing the substrate to a metal chloride containing gas while heating the substrate to a temperature of about 450° C. or less.

11. The method of claim 10, wherein the metal chloride comprises one or more of TiCl₄, AlCl₃, MoCl₅, MoCl₆, WCl₅, and WCl₆.

12. The method of claim 10, wherein the plasma comprises a capacitively coupled plasma (CCP), an inductively coupled plasma (ICP), or combinations thereof.

13. The method of claim 12, wherein the plasma comprises H₂.

14. The method of claim 13, wherein the substrate is exposed to the plasma for about 0.1 seconds to about 300 seconds.

15. The method of claim 11, further comprising incubating the substrate with the metal chloride for about 10 seconds to about 1,500 seconds.

16. The method of claim 12, wherein exposing the substrate to the plasma further comprises:
flowing a treatment gas into a process chamber and providing a RF power of between about 0.1 Watts and about 1,000 Watts to the process chamber.

17. The method of claim 10, wherein the insulating material is selectively etched.

18. The method of claim 17, wherein etching the insulating material has an etch selectively of about 5 or greater.

19. A dry etching method for etching materials on semiconductor substrates comprising:
providing a substrate comprising a gate material and an insulating material disposed at least partially around the gate material, the insulating material comprising HfO₂;
damaging an exposed surface of the insulating material by exposing the substrate to a plasma;
reacting the exposed surface of the insulating material with a metal chloride to form HfCl₄; and
removing a portion of the exposed surface of the insulating material.

20. The method of claim 19, further comprising cyclically repeating damaging the exposed surface and reacting the exposed surface.
